(19) United States
(12) Patent Application Publication
(10) Pub. No.: US 2026/0182400 A1
(43) Pub. Date: Jun. 25, 2026

(54) ELECTRONIC DEVICE AND MANUFACTURING METHOD THEREOF

(71) Applicant: Innolux Corporation, Miaoli County (TW)

(72) Inventors: Chen-Fang Hsiao, Miaoli County (TW); Po-Yun Hsu, Miaoli County (TW); Shun-Yi Yang, Miaoli County (TW); Meng-Hsuan Chuang, Miaoli County (TW); Chih-Yang Liu, Miaoli County (TW)

(73) Assignee: Innolux Corporation, Miaoli County (TW)

(21) Appl. No.: 19/398,070

(22) Filed: Nov. 24, 2025

Related U.S. Application Data
(60) Provisional application No. 63/737,799, filed on Dec. 23, 2024.

(30) Foreign Application Priority Data
Aug. 12, 2025 (CN) 202511125328.0

(51) Int. Cl. H01L 23/538; H01L 21/48; H01L 23/00; H01L 25/065

(52) U.S. Cl. CPC H10W 70/611; H10W 70/095; H10W 70/635; H10W 90/00; H10W 74/15; H10W 90/724; H10W 90/734

(57) ABSTRACT

A manufacturing method of an electronic device including following steps is provided. A substrate having a first surface and a second surface facing each other is provided. A plurality of localized regions of the substrate are modified. A first etching step is performed to form a plurality of holes in the localized regions. A second etching step is performed to form a plurality of through holes from the holes. Along a normal direction of the substrate, each of the holes has a first depth, each of the through holes has a second depth, and the first depth and the second depth satisfy a following equation (a): 0.5*T2≤T1≤T2, where T1 is the first depth, and T2 is the second depth.

### CROSS-REFERENCE TO RELATED APPLICATION

This application claims the priority benefit of U.S. provisional application No. 63/737,799, filed on Dec. 23, 2024, and China patent application no. 202511125328.0, filed on Aug. 12, 2025. The entirety of each of the above-mentioned patent applications is hereby incorporated by reference herein and made a part of this specification.

### BACKGROUND

### Technical Field

The disclosure relates to an electronic device; more particularly, the disclosure relates to a design and a manufacturing method of an electronic device having a through hole substrate.

### Description of Related Art

In a through hole substrate of an electronic device, e.g., a through glass via (TGV) substrate, through holes therein serve to enable electrical connection between components located on two opposite surfaces of the substrate. Therefore, increasing the current flowing through the through holes can improve the electrical performance of the electronic device.

To enhance the current flowing through the through holes, a taper angle between sidewalls of the through holes and the surfaces of the substrate can be reduced. However, achieving this requires process conditions with a relatively high etching selectivity ratio, which in turn increases the time required for manufacturing the electronic device, making large-scale production less sufficient.

### SUMMARY

The disclosure provides a manufacturing method of an electronic device that can reduce the manufacturing time of the electronic device while the electrical performance of the device is enhanced.

According to various embodiments of the disclosure, a manufacturing method of an electronic device includes following steps. A substrate is provided, where the substrate has a first surface and a second surface facing each other. A plurality of localized regions of the substrate are modified. A first etching step is performed to form a plurality of holes in the localized regions. A second etching step is performed to form a plurality of through holes from the holes. Along a normal direction of the substrate, each of the holes has a first depth, each of the through holes has a second depth, and the first depth and the second depth meet a following Equation (a). The disclosure can reduce process time for forming the electronic device while increasing electrical performance of the electronic device.

$$0.5 * T 2 ≦ T 1 ≦ T 2 , \qquad [ Equation ( a ) ]$$

wherein T1 is the first depth, and T2 is the second depth.

The disclosure further provides an electronic device, which can achieve relatively good electrical performance.

According to various embodiments of the disclosure, an electronic device includes a substrate, a plurality of through holes, and a circuit structure. The substrate has a first surface and a second surface facing each other. The through holes penetrate the substrate in a normal direction of the substrate. The circuit structure is disposed on the first surface of the substrate and includes a plurality of conductive layers and a plurality of insulating layers, where at least one portion of the conductive layers is disposed in the through holes. The through holes meet an Equation (d), an Equation (e), and an Equation (f).

$$0 ° ≦ a ≦ 20 ° , \qquad [ Equation ( d ) ]$$

wherein a is a taper angle between the first surface or the second surface of the substrate and sidewalls of the through holes.

$$1 ≦ W 2 / ( 0.5 * ( Wt + Wb ) ) ≦ 1.5 , \qquad [ Equation ( e ) ]$$

where W2 is the minimum width of the through holes in a direction perpendicular to the normal direction of the substrate, Wt is a width of the through holes near the first surface in the direction perpendicular to the normal direction of the substrate, and Wb is a width of the through holes near the second surface in the direction perpendicular to the normal direction of the substrate.

$$\vert ( W 21 - W 22 ) \vert / W 22 < 0.15 , \qquad [ Equation ( f ) ]$$

where W21 is the minimum width of one of the through holes in the direction perpendicular to the normal direction of the substrate, and W22 is the minimum width of another of the through holes in the direction perpendicular to the normal direction of the substrate.

To make the above more comprehensible, several embodiments accompanied with a drawing are described in detail as follows.

### BRIEF DESCRIPTION OF THE DRAWING

The accompanying drawings are included to provide a further understanding of the disclosure, and is incorporated in and constitute a part of this specification. The drawings illustrate embodiments of the disclosure and, together with the description, serves to explain the principles of the disclosure.

FIG. 1 is a schematic flowchart of a manufacturing method of an electronic device according to an embodiment of the disclosure.

FIG. 2A is a schematic cross-sectional diagram of holes in a substrate according to an embodiment of the disclosure.

FIG. 2B is a schematic cross-sectional diagram of holes in a substrate according to another embodiment of the disclosure.

FIG. 2C is a schematic cross-sectional diagram of holes in a substrate according to still another embodiment of the disclosure.

FIG. 3A is a schematic cross-sectional diagram of through holes in a substrate according to an embodiment of the disclosure.

FIG. 3B is a schematic cross-sectional diagram of through holes in a substrate according to another embodiment of the disclosure.

FIG. 4 is a schematic cross-sectional diagram of an electronic device according to an embodiment of the disclosure.

FIG. 5A to FIG. 5C are schematic diagrams of equipment for forming holes and/or through holes in a substrate according to an embodiment of the disclosure.

### DESCRIPTION OF THE EMBODIMENTS

Reference will now be made in detail to exemplary embodiments of the disclosure, and examples of the exemplary embodiments are illustrated in the accompanying drawings. Wherever possible, the same reference numbers are used in the drawings and the description to refer to the same or like parts.

The disclosure may be understood through reference to the following detailed description in conjunction with the accompanying drawings. It should be noted that, for ease of understanding by readers and for simplicity of the drawings, multiple drawings in the disclosure simply illustrate one portion of the electronic device, and specific elements in the drawings are not drawn to actual scale. Furthermore, the number and dimensions of each element in the drawings are merely schematic and are not intended to limit the scope of the disclosure.

Certain terminologies are used throughout the specification and the appended claims of the disclosure to refer to specific elements. Those skilled in the pertinent art should understand that electronic device manufacturers may refer to the same element by different names. This disclosure does not intend to distinguish between elements that have the same function but different names. In the following specification and claims, terminologies such as “include,” “contain,” and “have” are open-ended terms and should therefore be interpreted as meaning “including but not limited to.” Accordingly, when the terminologies “include,” “contain,” and/or “have” are used in the description of the disclosure, they specify the presence of corresponding features, regions, steps, operations, and/or components, but do not exclude the presence of one or more corresponding features, regions, steps, operations, and/or components.

Directional terminologies mentioned herein, such as “upper,” “lower,” “front,” “rear,” “left,” “right,” and so on, are merely references to the directions of the accompanying drawings. Therefore, the directional terminologies used are for illustration and are not intended to limit the disclosure. In the accompanying drawings, each figure illustrates general features of methods, structures, and/or materials used in specific embodiments. However, these figures should not be interpreted as defining or limiting the scope or nature covered by these embodiments. For instance, the relative dimensions, thickness, and positions of various layers, regions, and/or structures may be reduced or enlarged for clarity.

When a corresponding component (e.g., a layer or a region) is referred to as being “on another component,” it may be directly on the other component, or there may be other components present between them. On the other hand, when a component is referred to as being “directly on another component,” no components exist between them. Additionally, when a component is referred to as being “on another component,” the two have a vertical relationship in a top view direction, and this component may be above or below the other component, with this vertical relationship depending on the orientation of the device.

The terminologies “equal to” or “same,” “substantially,” or “approximately” are generally interpreted as being within 20% of a given value or range, or interpreted as being within 10%, 1%, or 0.5% of a given value or range.

The ordinal numbers used in the specification and claims, such as “first,” “second,” and so on, are used to modify elements, and do not inherently imply or represent that the elements have any preceding ordinal numbers, nor do they represent the order of one element relative to another element, or the order in manufacturing methods. The use of these ordinal numbers is solely to enable clear distinction between an element with a certain designation and another element with the same designation. The same terminology may not be used in the claims and specification; accordingly, a first component in the specification may be a second component in the claims.

It should be noted that the following embodiments may substitute, reorganize, and mix features from several different embodiments to complete other embodiments without departing from the spirit of the disclosure. Features between embodiments may be arbitrarily mixed and matched for use as long as they do not violate the spirit of the invention or conflict with each other.

The electrical connections or coupling relationships described in this disclosure may refer to direct connections or indirect connections. In the case of direct connections, the terminals of elements on two circuits are directly connected or connected to each other through a conductive line segment. In the case of indirect connections, switches, diodes, capacitors, inductors, other suitable elements, or combinations of the above elements are present between the terminals of elements on two circuits, but are not limited thereto.

In this disclosure, the measurement methods for thickness, length, width, and area may be obtained using optical microscope measurement, and thickness may be obtained by measurement from cross-sectional images in an electron microscope, but are not limited thereto. Additionally, any two values or directions used for comparison may have a certain error. If a first value is equal to a second value, it implies that there may be approximately 10% error between the first value and the second value; if a first direction is perpendicular to a second direction, the angle between the first direction and the second direction may range from 80 degrees to 100 degrees; if a first direction is parallel to a second direction, the angle between the first direction and the second direction may range from 0 degree to 10 degrees.

The manufacturing process of the electronic device provided in this disclosure may be provided through, for instance, a wafer-level package (WLP) process or a panel-level package (PLP) process, which may be a chip first process or a chip last/RDL first process.

The electronic device provided in this disclosure may be applied to high performance computing, power modules, semiconductor packaging devices, display devices, light-emitting devices, backlight devices, antenna devices, sensing devices, or splicing devices, which should however not be construed as limitations in the disclosure. It should be noted that the electronic device may be any combination of the aforementioned, which should however not be construed as limitations in the disclosure. Additionally, the external shape of the electronic device may be rectangular, circular, polygonal, a shape with curved edges, or other suitable shapes. The electronic device may have peripheral systems such as driving systems, control systems, and light source systems to support display devices, antenna devices, wearable devices, vehicle-mounted devices, or splicing devices. The electronic device may include electronic units, wherein the electronic elements may include passive elements and active elements, e.g., capacitors, resistors, inductors, diodes, transistors, sensors, etc. It should be noted that the electronic device provided in this disclosure may be various combinations of the above devices, but is not limited thereto. The electronic device may include packaging devices, such as high bandwidth memory (HBM) packaging, chip on wafer on substrate (CoWoS) packaging structures, system on a chip (SoC), system in a package (SiP), antenna in package (AiP), co-packaged optics (CPO), or various combinations of the above devices, which should however not be construed as limitations in the disclosure.

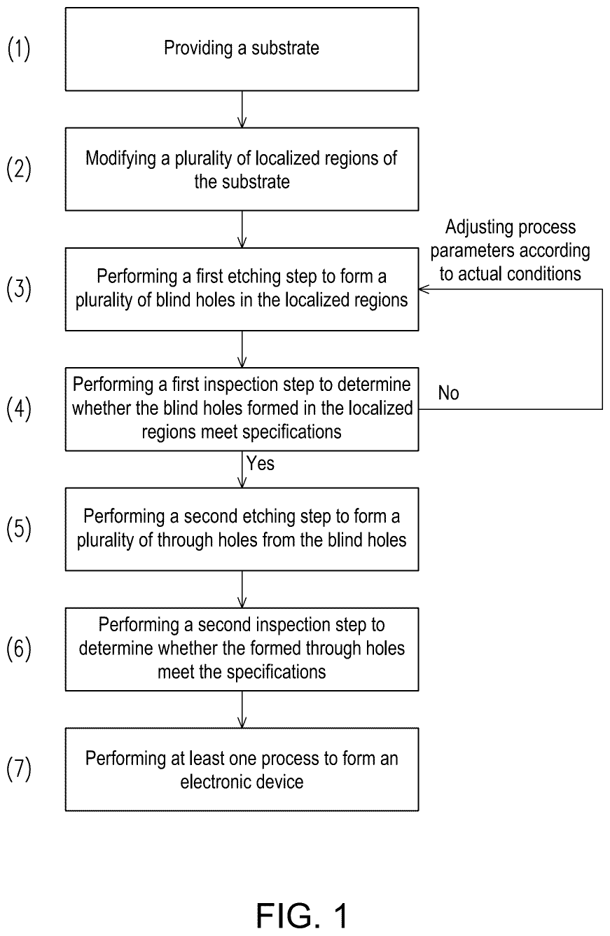

FIG. 1 is a schematic flowchart of a manufacturing method of an electronic device according to an embodiment of the disclosure.

With reference to FIG. 1, in this embodiment, the electronic device 1 may be formed by performing following steps, which should however not be construed as a limitation in the disclosure.

Step (1) is performed: a substrate 10 is provided.

A material of the substrate 10 may include, for instance, a suitable ceramic material. For instance, the material of the substrate 10 includes a transparent material, glass, alkali-free glass, and quartz glass, which should however not be construed as limitations in the disclosure. In this embodiment, the substrate 10 is a glass substrate, which should however not be construed as a limitation in the disclosure. In some embodiments, the substrate 10 may be formed by stacking a plurality of sub-substrates. For instance, the substrate 10 may be formed by performing a heating process, a pressurizing process, a bonding process, other suitable processes, or combinations thereof on two or more sub-substrates (not shown), which should however not be construed as a limitation in the disclosure. In this embodiment, the substrate 10 has a surface 10s1 and a surface 10s2 facing each other in a direction Z (a normal direction of the substrate 10).

Step (2) is performed: a plurality of localized regions 10A of the substrate 10 are modified.

In some embodiments, a plurality of localized regions 10A separated from each other may be defined in the substrate 10, where the localized regions 10A are regions predetermined to form holes therein. It is worth noting that the “holes” described herein in this embodiment may include blind holes or through holes, which should however not be construed as a limitation in the disclosure.

In some embodiments, the localized regions 10A of the substrate 10 may be modified by performing a laser process. In detail, the laser process may be performed on the localized regions 10A respectively from the surface 10s1 of the substrate 10, which may make the modified localized regions 10A easy to be removed by subsequent etching processes to be performed.

Step (3) is performed: a first etching step is performed to form a plurality of holes VH in the localized regions 10A, where the holes VH may include blind holes and through holes.

In this embodiment, the first etching step is a wet etching process, which should however not be construed as a limitation in the disclosure. In some embodiments, an etchant used in the first etching step may include an acidic etchant, an alkaline etchant, an inhibitor, or a mixture of any two of the above. For instance, a volume ratio of the inhibitor to the etchant may be greater than or equal to 0.001 and less than or equal to 0.5; that is, adding 1 milliliter of inhibitor to 1 liter of etchant. The acidic etchant may at least include hydrofluoric acid (HF), and the alkaline etchant may include sodium hydroxide (NaOH), potassium hydroxide (KOH), or a mixture of the above.

By modifying the localized regions 10A of the substrate 10 in step (2), an etching rate of the localized regions 10A may be increased. In detail, under the process conditions of the first etching step, the localized regions 10A of the substrate 10 may have a relatively high first etching selectivity ratio compared to the remaining regions of the substrate 10. Therefore, when the first etching step is performed, the etching rate of the localized regions 10A of the substrate 10 is greater than the etching rate of the remaining regions of the substrate 10, so as to form the holes VH in the localized regions 10A. That is, at least one portion of the substrate 10 is removed to form the holes VH.

It is worth noting that the process conditions for achieving the “first etching selectivity ratio” will be described in detail in the following step (6) for comparison with the “second etching selectivity ratio” mentioned in step (6).

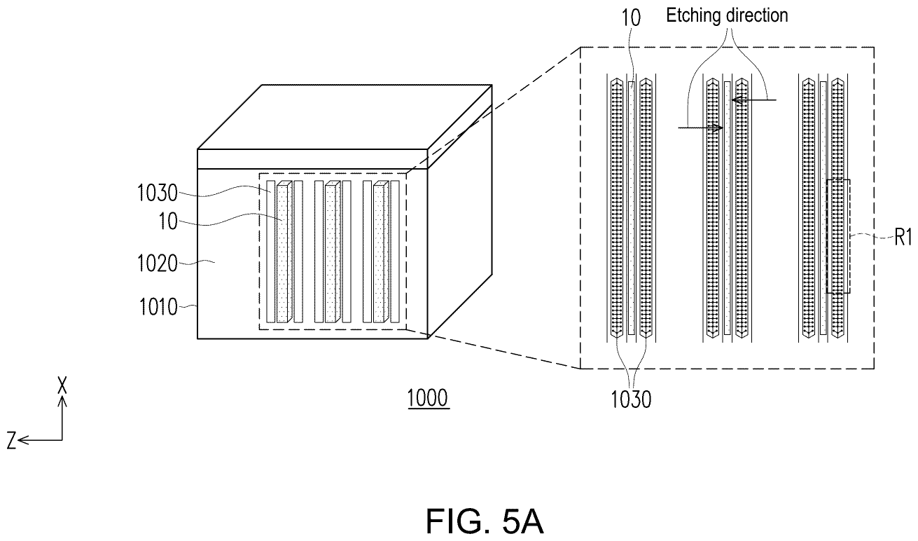

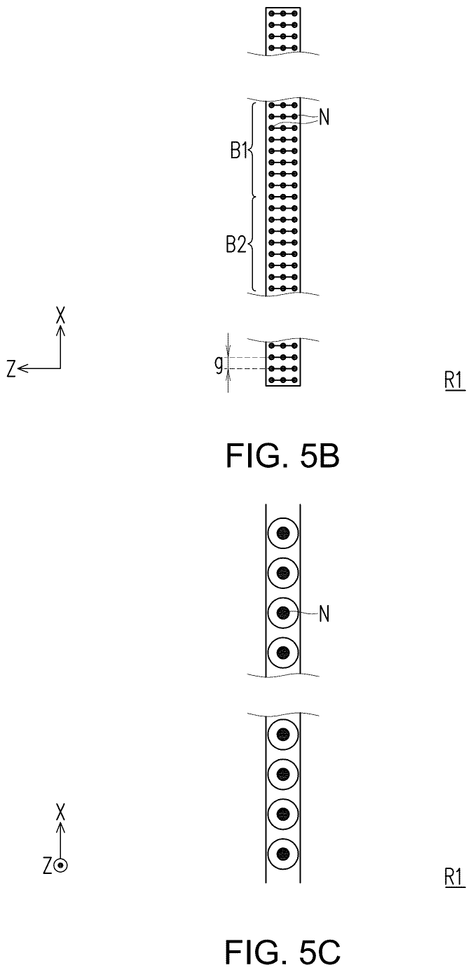

In some embodiments, the first etching step may be performed using an etching equipment 1000 shown in FIG. 5A. The etching equipment 1000 includes, for instance, an etching tank 1010, an etchant 1020, and a tube array element 1030. The etching tank 1010 is configured, for instance, to accommodate the etchant 1020 and a plurality of the substrates 10 to undergo etching reactions. The type of the etchant 1020 may refer to the above embodiments and will not be described in detail hereinafter. The tube array element 1030 includes, for instance, a plurality of regions. Different process parameters may be provided in any two regions of the tube array element 1030 (e.g., a region B1 and a region B2), where the process parameters may include pressure, flow rate, angle, temperature, or other suitable process parameters. In this embodiment, with reference to FIG. 5B and FIG. 5C, the tube array element 1030 includes a plurality of nozzle units N, which may rotate 360 degrees. There is a gap g between two adjacent nozzle units N, and the gap g is, for instance, less than or equal to 5 mm. In some embodiments, an etching direction of the etchant 1020 sprayed from the nozzle units N may be −45 degrees (rotating 45 degrees counterclockwise with a direction Z as the axis) to 45 degrees (rotating 45 degrees clockwise with the direction Z as the axis), so as to improve the etching rate. In some embodiments, the tube array element 1030 may be fixed in the etching tank 1010, which should however not be construed as a limitation in the disclosure. In other embodiments, the tube array element 1030 may be separated from the etching tank 1010. When the etching step is performed, the substrate 10 is positioned between at least two adjacent tube array elements 1030. In other words, the substrate 10 is substantially parallel to at least two adjacent tube array elements 1030. When the etchant 1020 is sprayed from the nozzle units N, the etching rate may be improved.

Step (4) is performed: a first inspection step is performed to determine whether the holes VH formed in the localized regions 10A meet specifications.

Specifically, in this embodiment, the first inspection step is performed to determine whether the holes VH meet the following relational expressions: Equation (a) 0.5*T2≤T1≤T2; Equation (b) 0.05≤W1/W2≤0.5; Equation (c) |(T12−T11)/T12<0.15.

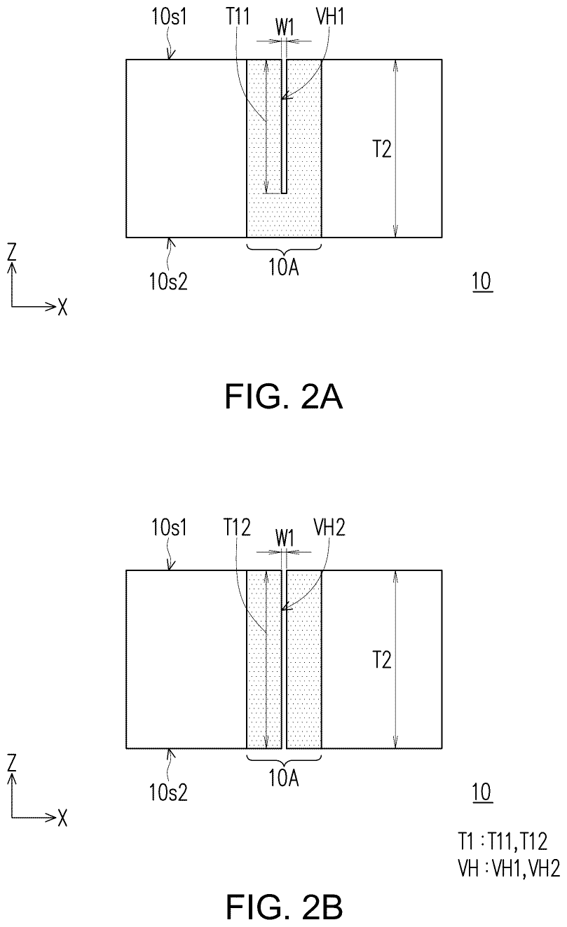

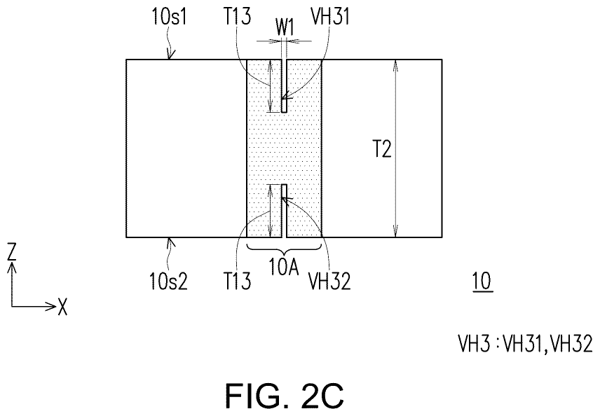

In the Equation (a), the holes VH have a depth T1 in the direction Z, and the substrate 10 has a thickness T2 in the direction Z (or a depth T2 of the through holes TH to be introduced below), and the depth T1 of the holes VH and the thickness T2 of the substrate 10 meet the Equation (a): 0.5*T2≤T1≤T2. In detail, please refer to FIG. 2A and FIG. 2B, which show the types of the blind holes and the through holes among the holes VH, i.e., a hole VH1 and a hole VH2, respectively. A depth T11 of the hole VH1 and the thickness T2 of the substrate 10 meet the following relational expression: 0.5*T2≤T11≤T2, and a depth T12 of the hole VH2 and the thickness T2 of the substrate 10 meet the following relational expression: 0.5*T2≤T25≤T2.

In the Equation (b), the holes VH have the minimum width W1 in a direction X, the through holes TH to be formed in step (6) have the minimum width W2 in the direction X, and the minimum width W1 of the holes VH and the minimum width W2 of the through holes TH meet the Equation (b): 0.05≤W1/W2≤0.5.

In the Equation (c), with reference to FIG. 2A and FIG. 2B, in the blind holes and the through holes among the holes VH (e.g., the hole VH1 and the hole VH2), a ratio of an absolute value of the difference between the depth T11 of the hole VH1 and the depth T12 of the hole VH2 to the maximum value of the depth T11 and the depth T12 may be less than 0.15, i.e., the Equation (c): |(T12−T11)|/T12<0.15 is satisfied. In other words, the dimensions of the blind holes and the dimensions of the through holes among the holes VH are similar.

In some embodiments, whether the holes VH meet the Equation (a), the Equation (b), and the Equation (c) may be determined through an optical inspection system (OM) or an automatic optical inspection system (AOI), but this disclosure is not limited to these inspection methods.

In some embodiments, the substrate 10 may be cleansed before the first inspection step is performed, which should however not be construed as a limitation in the disclosure.

It is worth noting that the types of the holes VH are not limited to the hole VH1 and the hole VH2 shown in FIG. 2A and FIG. 2B. With reference to FIG. 2C, holes VH3 includes a hole VH31 extending from the surface 10s1 of the substrate 10 toward a direction opposite to the direction Z and includes a hole VH32 extending from the surface 10s2 of the substrate 10 toward the direction Z. The hole VH31 and the hole VH32 may both have the substantially equal depth T13, and the total depth (2*T13) of the hole VH31 and the hole VH32 corresponds to T1 in the Equation (a).

After step (4) is performed, if the holes VH do not meet at least one of the Equation (a), the Equation (b), and the Equation (c), then return to step (3), where a third etching step may be performed by adjusting the process parameters of step (3) to modify the holes VH, thereby increasing the possibility that the subsequently formed holes VH meet the Equation (a), the Equation (b), and the Equation (c). In contrast, after step (4) is performed, if the holes VH meet the Equation (a), the Equation (b), and the Equation (c), then the following step (5) is performed.

Step (5) is performed: a second etching step is performed to form a plurality of through holes TH from the holes VH.

In this embodiment, the second etching step is a wet etching process, which should however not be construed as a limitation in the disclosure. In some embodiments, the etchant used in the second etching step may include an acidic etchant or an alkaline etchant, where the acidic etchant may include HF, and the alkaline etchant may include NaOH or KOH.

By modifying the localized regions 10A of the substrate 10 in step (2), the etching rate of the localized regions 10A may be increased. Specifically, under the process conditions of the second etching step, the remaining portions of the localized regions 10A of the substrate 10 may have a relatively high second etching selectivity compared to the remaining regions of the substrate 10. Therefore, when the second etching step is performed, the etching rate of the localized regions 10A of the substrate 10 is greater than the etching rate of the remaining regions of the substrate 10, so that the holes VH already formed in the localized regions 10A further expand and penetrate the surface 10s2 of the substrate 10 to form the through holes TH. Accordingly, the formed through holes TH may penetrate the surface 10s1 and the surface 10s2 of the substrate 10 in the normal direction of the substrate.

In this embodiment, the second etching selectivity may be less than or equal to the first etching selectivity, and the process conditions of the second etching step and the process conditions of the first etching step in step (3) are listed in Table 1 and Table 2 below, which should however not be construed as a limitation in the disclosure.

TABLE 1
The etchant used in the first etching
step and the second etching step is HF.

| | Etchant | Etchant |
|---|---|---|
| | concentration (%) | temperature (° C.) |
| Process conditions of the | 0.01 to 1.5 | 10 to 25 |
| first etching step | | |
| Process conditions of the | 2.0 to 15 | 15 to 60 |
| second etching step | | |

TABLE 2
The etchant used in the first etching step
and the second etching step is NaOH or KOH.

| | Etchant | Etchant |
|---|---|---|
| | concentration (%) | temperature (° C.) |
| Process conditions of the | 5 to 50 | 10 to 100 |
| first etching step | | |
| Process conditions of the | 5 to 50 | 110 to 145 |
| second etching step | | |

Step (6) is performed: a second inspection step is performed to determine whether the formed through holes TH meet the specifications.

Specifically, in this embodiment, the second inspection step is performed to determine whether the through holes TH meet the following relational expressions: Equation (d) 0°≤a≤20°; Equation (e) 1≤W2/(0.5*(Wt+Wb))≤1.5; Equation (f) |(W21−W22)|/W22<0.15.

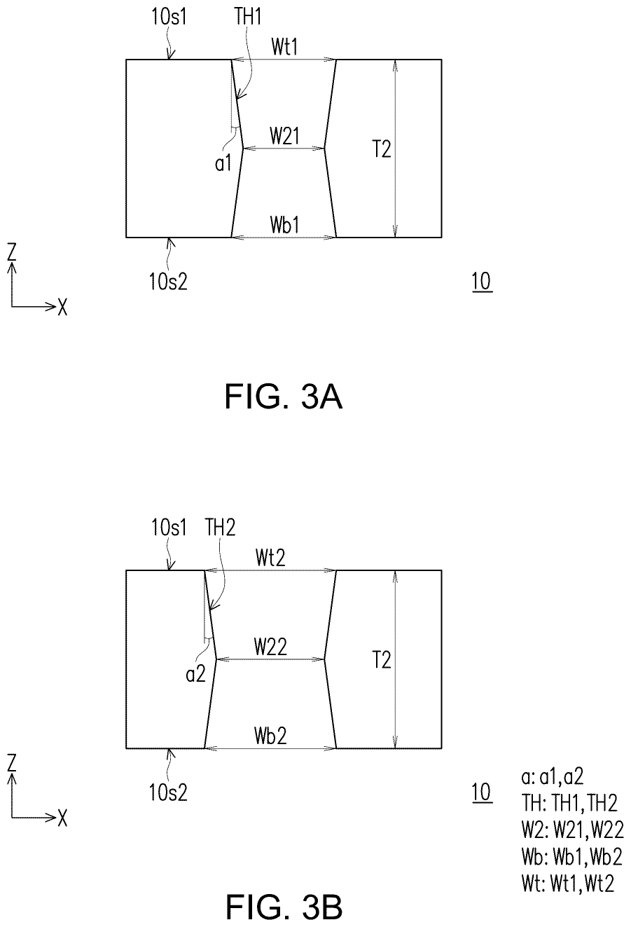

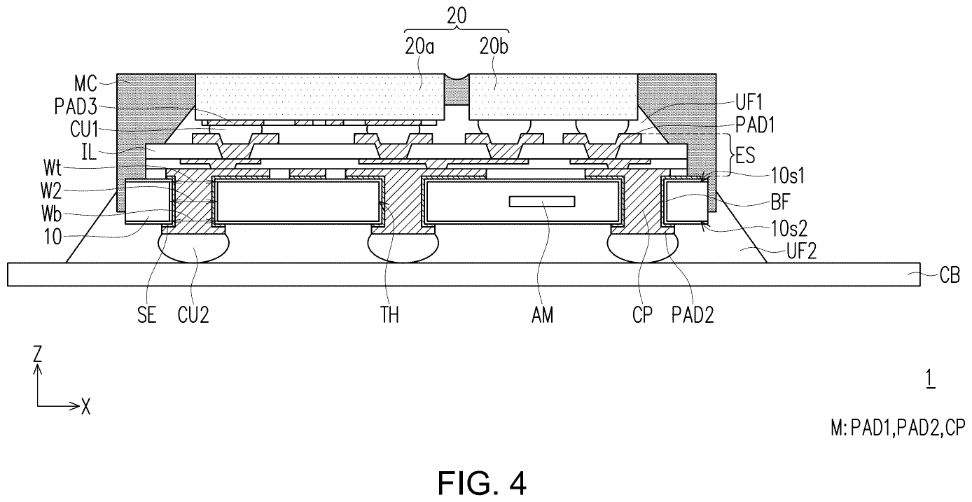

In the Equation (d), the through holes TH have a dumbbell-shaped or hourglass-shaped configuration; therefore, the through holes TH have a taper angle a, where the taper angle a is defined by the surface 10s1 (or the surface 10s2) of the substrate 10 and the sidewalls of the through holes. Specifically, please refer to FIG. 3A and FIG. 3B, which show two through holes among the through holes TH, i.e., a through hole TH1 and a through hole TH2. A taper angle a1 of the through hole TH1 meets the following relational expression: 0°≤a1≤20°, and a taper angle a2 of the through hole TH2 meets the following relational expression: 0°≤a2≤20°.

In the Equation (e), the through holes TH have the minimum width W2 in the direction X (approximately located at the center of the through holes TH), and the through holes TH have a width Wt and a width Wb respectively closest to the surface 10s1 and the surface 10s2 in the direction X. Specifically, with reference to FIG. 3A and FIG. 3B, the minimum width W21 of the through hole TH1 and the width Wt1 and the width Wb1 meet the following relational expression: W21/(0.5*(Wt1+Wb1))≤1.5, and the minimum width W22 of the through hole TH2 and the width Wt2 and the width Wb2 meet the following relational expression: W22/(0.5*(Wt2+Wb2))≤1.5.

In the Equation (f), with reference to FIG. 3A and FIG. 3B, in any two through holes among the through holes TH (e.g., the through hole TH1 and the through hole TH2), a ratio of an absolute value of a difference between the minimum width W21 of the through hole TH1 and the minimum width W22 of the through hole TH2 to the maximum value among the minimum width W21 and the minimum width W22 is less than 0.15, i.e., the Equation (f): |(W21−W22)|/W22<0.15 is satisfied. In other words, the dimensions of any two through holes among the through holes TH are similar.

In some embodiments, whether the through holes TH meet the Equation (d), the Equation (e), and the Equation (f) may be determined through the OM or the AOL, but this disclosure is not limited to these inspection methods.

Step (7) is performed: at least one process is performed to form the electronic device 1.

In this embodiment, at least one corresponding process may be performed on the substrate 10 to form the electronic device 1, and the process may include processes of forming a circuit structure ES and forming a plurality of electronic elements 20 on the substrate 10, which should however not be construed as a limitation in the disclosure.

In this embodiment, the circuit structure ES is disposed on the surface 10s1 of the substrate 10 and at least partially overlaps the through holes TH. In some embodiments, the circuit structure ES includes a plurality of insulating layers IL and a plurality of conductive layers M. The insulating layers IL may be, for instance, Ajinomoto build-up film (ABF), which should however not be construed as a limitation in the disclosure. In other embodiments, a material of the insulating layers IL may include photosensitive polyimide (PSPI), polyimide (PI), polybenzoxazole (PBO), epoxy, isophthalic amine, or other suitable insulating materials. The conductive layers M may include suitable conductive materials. In some embodiments, a material of the conductive layers M may include copper (Cu), aluminum (Al), molybdenum (Mo), tungsten (W), gold (Au), chromium (Cr), nickel (Ni), platinum (Pt), titanium (Ti), silver (Ag), tantalum (Ta), metal nitrides, other suitable conductive materials, or any combination thereof, which should however not be construed as limitations in the disclosure. In some embodiments, before the conductive layers M are formed, a seed layer SE may be first formed on the substrate 10, where the seed layer SE is disposed in at least one portion of the through holes TH. A material of the seed layer SE may include, for instance, titanium nitride, Ti, ruthenium, Cu, Ag, Au, Al, tin, Ni, or combinations thereof, which should however not be construed as a limitation in the disclosure.

In this embodiment, the conductive layers M in the circuit structure ES include pads PAD1, pads PAD2, and connection elements CP. The pads PAD1 are located, for instance, on one side of the surface 10s1 of the substrate 10, and are a portion of the conductive layers M farthest from the surface 10s1 of the substrate 10 and exposed by the insulating layers IL. The pads PAD2 are located, for instance, on one side of the surface 10s2 of the substrate 10. In this embodiment, at least one portion of the conductive layers M is disposed in the through holes TH. In detail, the connection elements CP are portions of the conductive layers M other than the pads PAD1 and the pads PAD2 and disposed between adjacent insulating layers IL and in the through holes TH for establishing an electrical connection path between the pads PAD1 and the pads PAD2.

In this embodiment, the circuit structure ES includes a redistribution structure, which may be used for redistributing wiring and/or further enhancing a wiring fan-out area. The purpose of disposing the redistribution structure is to extend connections to wider pitches or redistribute connections to another connection having different pitches. Accordingly, the electronic elements 20 that are the same as or different from each other may be disposed on and electrically connected to the circuit structure ES, and a main board CB may be disposed on the surface 10s2 of the substrate 10 and electrically connected to the circuit structure ES through the through holes TH, such that the electronic device 100 may be electrically connected to the main board CB through the circuit structure ES.

In this embodiment, the electronic device 1 further includes a buffer layer BF. A material of the buffer layer BF may include suitable organic materials and/or inorganic materials. For instance, the material of the buffer layer BF may include PI, parylene, benzocyclobutene (BCB) resin, epoxy, polycarbonate (PC), polyethylene terephthalate (PET), polyethylene naphthalate (PEN), silicon-containing compounds, or combinations thereof, which should however not be construed as a limitation in the disclosure. In some embodiments, the buffer layer BF may include a multi-layer structure. For instance, the buffer layer BF may have a stacked configuration including an inorganic layer/an organic layer/an inorganic layer. In some embodiments, the buffer layer BF may cover the sidewalls of the substrate 10 and the sidewalls of the through holes TH and may function to fill pits, surface irregularities, or microcracks formed on the corresponding surfaces of the substrate 10 during the process. Such coverage can advantageously reduce the likelihood of defects in the subsequently formed seed layer SE and/or the conductive layers M.

The electronic elements 20 are disposed on and electrically connected to the circuit structure ES, for instance. In this embodiment, the electronic elements 20 include two electronic elements 20a and 20b, but the quantities should not be construed as limitations in this disclosure. The electronic elements 20a and 20b may be, for instance, high bandwidth memory (HBM), dynamic random access memory (DRAM), static random access memory (SRAM), cache memory, graphic processing unit (GPU), central processing unit (CPU), digital signal processor (DSP), or application-specific integrated circuit (ASIC), which should however not be construed as a limitation in the disclosure. The electronic element 20a may be electrically connected to the circuit structure ES through a contact pad PAD3 and at least one portion of the connection units CU1, and the electronic element 20b may be electrically connected to the circuit structure ES through at least another portion of the random-access connection units CU1.

In this embodiment, the electronic device 1 further includes a plurality of connection units CU1. The connection units CU1 are disposed on the circuit structure ES and electrically connected to the contact pads PAD1 in the circuit structure ES, for instance, so that the circuit structure ES may be electrically connected to the electronic elements 20 through the connection units CU1. A material of the connection units CU1 may include tin, Cu, Ni, Ag, Au, gallium, or other suitable materials. For instance, the connection units CU1 may be solder balls, which should however not be construed as a limitation in the disclosure.

In this embodiment, the electronic device 1 further includes an encapsulation layer MC. The encapsulation layer MC encapsulates the substrate 10 and surrounds the electronic elements 20, for instance. In this embodiment, the encapsulation layer MC may expose one portion of the electronic elements 20. In detail, an upper surface of the encapsulation layer MC may be aligned to non-active surfaces of the electronic elements 20, which should however not be construed as a limitation in the disclosure. In some embodiments, a material of the encapsulation layer MC may include epoxy molding compound (EMC), which should however not be construed as a limitation in the disclosure. In other embodiments, the encapsulation layer MC may include EMC with silicon dioxide particles dispersed therein.

In this embodiment, the electronic device 1 further includes an adhesive layer UF1. The adhesive layer UF1 is disposed between the substrate 10 and the electronic elements 20 and fills the space between the adjacent connection elements CU1, for instance. In some embodiments, the adhesive layer UF1 may be surrounded by the encapsulation layer MC. A material of the adhesive layer UF1 may include suitable inorganic materials or organic materials, which should however not be construed as a limitation in the disclosure.

In this embodiment, the electronic device 1 further includes a plurality of connection units CU2. The connection units CU2 are disposed on one side of the surface 10s2 of the substrate 10 and electrically connected to the contact pads PAD2 in the circuit structure ES, for instance, so that circuit structure ES may be electrically connected to the main board CB through the connection units CU2. In some embodiments, the electrical connection to the main board CB may be achieved through an alignment mark AM in the substrate 10, which should however not be construed as a limitation in the disclosure. A material of the connection units CU2 may be the same as or similar to the material of the connection units CU1 and thus will not be described in detail herein.

In this embodiment, the electronic device 1 further includes an adhesive layer UF2. The adhesive layer UF2 is disposed between the substrate 10 and the main board CB and fills the space between the adjacent connection elements CU2, for instance. In some embodiments, the adhesive layer UF2 may contact the sidewall of the encapsulation layer MC. A material of the adhesive layer UF2 may include suitable inorganic materials or organic materials, which should however not be construed as a limitation in the disclosure.

To summarize, in the manufacturing method of the electronic device provided in one or more embodiments of the disclosure, the through holes are formed by sequentially performing the first etching step followed by the second etching step. The process conditions of the first etching step and the second etching step respectively exhibit a first etching selectivity ratio and a second etching selectivity ratio, and the second etching selectivity ratio is less than the first etching selectivity ratio. Therefore, after the holes are formed in the first etching step, which employs a relatively high first etching selectivity ratio, the through holes are formed in the second etching step which employs a relatively low second etching selectivity ratio. In this manner, the widths of the holes remain substantially uniform, and the through holes are obtained by further enlarging the initially formed holes. Such a configuration can reduce overall process time while also reducing the taper angle between the sidewalls of the through holes and the surface of the substrate.

It will be apparent to those skilled in the art that various modifications and variations may be made to the disclosed embodiments without departing from the scope or spirit of the disclosure. In view of the foregoing, it is intended that the disclosure covers modifications and variations provided they fall within the scope of the following claims and their equivalents.

What is claimed is:

1. A manufacturing method of an electronic device, comprising:
providing a substrate, wherein the substrate has a first surface and a second surface facing each other;
modifying a plurality of localized regions of the substrate;
performing a first etching step to form a plurality of holes in the localized regions;
performing a second etching step to form a plurality of through holes from the holes,
wherein along a normal direction of the substrate, each of the holes has a first depth, each of the through holes has a second depth, and the first depth and the second depth satisfy a following Equation (a):
$$0.5 * T 2 \leq T 1 \leq T 2 , \qquad [ Equation ( a ) ]$$
wherein T1 is the first depth, and T2 is the second depth.

2. The manufacturing method according to claim 1, further comprising:
after forming the holes, performing a first inspection step to determine whether the holes meet specifications.

3. The manufacturing method according to claim 2, wherein the step of determining whether the holes meet the specifications comprises determining whether the holes meet the Equation (a), an Equation (b), and an Equation (c):
$$0.05 ≦ W 1 / W 2 ≦ 0.5 , \qquad [ Equation ( b ) ]$$
wherein W1 is a minimum width of the holes in a direction perpendicular to the normal direction of the substrate, and W2 is a minimum width of the through holes in the direction perpendicular to the normal direction of the substrate,
$$\vert ( T 12 - T 11 ) \vert / T 12 < 0.15 , \qquad [ Equation ( c ) ]$$
wherein T11 is a depth of one of the holes along the normal direction of the substrate, and T12 is a depth of another of the holes along the normal direction of the substrate.

4. The manufacturing method according to claim 1, wherein when the holes do not meet at least one of the Equation (a), the Equation (b), and the Equation (c), performing a third etching step to modify the holes, wherein process parameters of the third etching step are different from process parameters of the first etching step.

5. The manufacturing method according to claim 1, further comprising:
after forming the through holes, performing a second inspection step to determine whether the through holes meet specifications.

6. The manufacturing method according to claim 5, wherein the step of determining whether the through holes meet the specifications comprises determining whether the through holes meet an Equation (d), an Equation (e), and an Equation (f):
$$0 ° \leq a \leq 20 ° , \qquad [ Equation ( d ) ]$$
wherein a is a taper angle between the first surface or the second surface of the substrate and sidewalls of the through holes,
$$1 \leq W 2 / ( 0.5 * ( Wt + Wb ) ) \leq 1.5 , \qquad [ Equation ( e ) ]$$
wherein W2 is a minimum width of the through holes in a direction perpendicular to the normal direction of the substrate, Wt is a width of the through holes near the first surface of the substrate in the direction perpendicular to the normal direction of the substrate, and Wb is a width of the through holes near the second surface of the substrate in the direction perpendicular to the normal direction of the substrate,
$$\vert ( W 21 - W 22 ) \vert / W 22 < 0.15 , \qquad [ Equation ( f ) ]$$
wherein W21 is a minimum width of one of the through holes in the direction perpendicular to the normal direction of the substrate, and W22 is a minimum width of another of the through holes in the direction perpendicular to the normal direction of the substrate.

7. The manufacturing method according to claim 5, further comprising:
after performing the second inspection step, performing at least one process to form the electronic device, wherein the at least one process comprises a process for forming a circuit structure.

8. The manufacturing method according to claim 7, wherein the circuit structure comprises a redistribution layer.

9. The manufacturing method according to claim 1, wherein the first etching step and the second etching step are wet etching processes.

10. The manufacturing method according to claim 9, wherein an etchant used in the wet etching processes comprises an acidic etchant or an alkaline etchant, the acidic etchant comprises hydrofluoric acid, and the alkaline etchant comprises sodium hydroxide or potassium hydroxide.

11. The manufacturing method according to claim 10, wherein when the etchant used in the wet etching processes is the acidic etchant, a concentration of the etchant in the first etching step ranges from 0.01% to 1.5%, and a concentration of the etchant in the second etching step ranges from 2.0% to 15%.

12. The manufacturing method according to claim 11, wherein a temperature of the etchant in the first etching step ranges from 10° C. to 25° C., and a temperature of the etchant in the second etching step ranges from 15° C. to 60° C.

13. The manufacturing method according to claim 10, wherein when the etchant used in the wet etching processes is the alkaline etchant, a concentration of the etchant in the first etching step ranges from 5% to 50%, and a concentration of the etchant in the second etching step ranges from 5% to 50%.

14. The manufacturing method according to claim 13, wherein a temperature of the etchant in the first etching step ranges from 10° C. to 100° C., and a temperature of the etchant in the second etching step ranges from 110° C. to 145° C.

15. An electronic device, comprising:
a substrate, having a first surface and a second surface facing each other;
a plurality of through holes, penetrating the substrate in a normal direction of the substrate; and
a circuit structure, disposed on the first surface of the substrate and comprising a plurality of conductive layers and a plurality of insulating layers, wherein at least one portion of the conductive layers is disposed in the through holes,
wherein the through holes meet an Equation (d), an Equation (e), and an Equation (f):
$$0 ° \leq a \leq 20 ° , \qquad [ Equation ( d ) ]$$
wherein a is a taper angle between the first surface or the second surface of the substrate and sidewalls of the through holes,
$$1 \leq W 2 / ( 0.5 * ( Wt + Wb ) ) \leq 1.5 , \qquad [ Equation ( e ) ]$$
wherein W2 is a minimum width of the through holes in a direction perpendicular to the normal direction of the substrate, Wt is a width of the through holes near the first surface of the substrate in the direction perpendicular to the normal direction of the substrate, and Wb is a width of the through holes near the second surface of the substrate in the direction perpendicular to the normal direction of the substrate,
$$\vert ( W 21 - W 22 ) \vert / W 22 < 0.15 , \qquad [ Equation ( f ) ]$$
wherein W21 is a minimum width of one of the through holes in the direction perpendicular to the normal direction of the substrate, and W22 is a minimum width of another of the through holes in the direction perpendicular to the normal direction of the substrate.

16. The electronic device according to claim 15, further comprising:
a plurality of electronic elements, disposed on the circuit structure and electrically connected to the circuit structure.

17. The electronic device according to claim 16, further comprising:
an encapsulation layer, surrounding the electronic elements.

18. The electronic device according to claim 15, wherein the circuit structure comprises a redistribution structure.

19. The electronic device according to claim 15, further comprising:
a seed layer, disposed in at least one portion of the through holes.

20. The electronic device according to claim 15, wherein the substrate is a glass substrate.
